(19) United States
(12) Patent Application Publication
(10) Pub. No.: US 2008/0099235 A1
(43) Pub. Date: May 1, 2008

(54) PRINTED-WIRING BOARD, METHOD FOR FORMING ELECTRODE OF THE BOARD, AND HARD DISK DEVICE

(75) Inventors: Syuji Hiramoto, Kokubunji-shi (JP); Makoto Aoki, Fukaya-shi (JP)

Correspondence Address: KNOBBE MARTENS OLSON & BEAR LLP, 2040 MAIN STREET, FOURTEENTH FLOOR, IRVINE, CA, 92614, US

(73) Assignee: Kabushiki Kaisha Toshiba, Tokyo (JP)

(21) Appl. No.: 11/929,611

(22) Filed: Oct. 30, 2007

(30) Foreign Application Priority Data
Oct. 31, 2006 (JP) 2006-296924

(51) Int. Cl. H05K 1/11; H05K 3/00; G11B 21/02

(52) U.S. Cl. 174/261; 29/843; 360/75

(57) ABSTRACT

According to one embodiment, there is provided a printed-wiring board on which an electrode for a semiconductor device bonding in a flip-chip-mounting manner is formed by an exposed part of a wiring pattern defined by a solder resist coating film, wherein the electrode includes an expanded section spreading in a line width direction of the wiring pattern to form the electrode.

### CROSS-REFERENCE TO RELATED APPLICATIONS

This application is based upon and claims the benefit of priority from Japanese Patent Application No. 2006-296924, filed Oct. 31, 2006, the entire contents of which are incorporated herein by reference.

### BACKGROUND

1. Field

One embodiment of the present invention relates to a printed-wiring board having electrodes on which a semiconductor device is to be flip-chip-bonded, each of the electrodes being formed at an exposed portion of a wiring pattern defined by a solder resist coating film.

2. Description of the Related Art

In a small-sized electronic equipment to be easily carried, a technique for mounting a semiconductor device such as a bare chip on a circuit board inside the equipment by flip-chip bonding has become widely used. As to a printed-wiring board used in a circuit board, a printed-wiring board having electrodes to be used for flip-chip bonding is used, in which the electrodes are formed at an exposed portion of a wiring pattern defined by the solder resist coating film. In the printed-wiring board coated with the solder resist coating film is provided with a wiring pattern area in which a plurality of wiring patterns arranged in a prescribed direction are exposed to form an electrode forming part for the flip-chip bonding. The exposed wiring patterns used as the electrodes are applied with plating using a metal such as Ni/Au alloy and Sn, if necessary.

The exposed electrodes thus formed each has a rectangle shape with a short side corresponding to a width of a wiring. Therefore, when an IC chip is flip-chip-bonded onto a printed-wiring board provided with the electrodes each having the rectangle shape, a solder bump of the IC having a ball like shape for example, will be deformed into a rectangle shape corresponding to that of the electrode. The short side of the bump is deformed in accordance with the wiring-width direction and a long side thereof is elongated along a line length direction of the wiring, so that the shape in the wiring width is relatively thinner (narrower) than that of in the line length direction. Accordingly, a bonding area or a wet-spreading area of the solder in the wiring width direction becomes extremely smaller than that in the line length direction. In other words, a bonding area or a wet-spreading area of the solder on a passivation side of the IC chip and that on the electrode side of the printed-wiring board become extremely different from each other.

In general, the long-term bonding reliability of a solder bonding part of a semiconductor component will be decreased due to the accumulation of the stress caused by a change in temperature of a surrounding environment, although the bonding part is reinforced with a buffer material such as an under-fill resin provided under the IC chip. The stress is generated due to a difference in thermal expansion coefficient between a silicon part of the IC chip and a resin part of the printed-wiring board. The accumulation of the stress will cause an occurrence of a clack at the solder bonding part. In this case, since the shapes of the solder bumps are different in a length direction and a width direction of wiring acting as the electrode, and the bonding or the wet-spreading areas of the solder on the passivation side of the IC chip and on the electrode side of the printed-wiring board are extremely different from each other, the vicinity of the solder bump bonding at the side of the passivation of the IC chip becomes weak against the thermal stress.

As for a technique coping with such a defect, there is a technique to form a solder pad shape of the printed-wiring board so that the central part of the solder pad is heaped. This technique is applicable to a semiconductor device of a type in which an IC chip such as a QFP is coated with a mold resin, but hard to apply it to mount a bare chip which requires electrode processing for forming electrodes arranged with a microscopic pitch. For example, Jpn. Utility Model Appln. KOKAI Publication No. 5-28073 teaches such a technique.

As mentioned above, the printed-wiring board is provided with the electrodes on which a semiconductor device is bonded in a flip-chip manner. The electrodes are formed at the exposed part of the wiring pattern defined by the solder resist coating film. Since the shape of the solder bumps is different in the solder wet-spreading area on the passivation side of the IC chip and on the electrode side of the printed-wiring board from each other, the difference therebetween poses a subject of a flip-chip bonding technique such that the passivation of the IC chip and the vicinity of the solder bump bonding become weak with respect to heat stress.

According to one aspect of the present invention, there is provided a printed-wiring board on which electrodes for semiconductor device bonding in a flip-chip-mounted manner are formed at an exposed part of a wiring pattern defined by a solder resist coating film, wherein the electrodes each includes an expanded section spreading in a line width direction of the wiring pattern to form the electrode at which the semiconductor device is bonded.

Another aspect of the present invention is a method for forming an electrode of a printed wiring board on which an electrode for semiconductor device bonding to be flip-chip-mounted is formed by an exposed section of a wiring pattern defined by a solder resist coating film, comprising forming the electrode for semiconductor device by disposing an expanded section spreading in a line width direction of the wiring pattern at the electrode, and by including the expanded section.

Still another aspect of the present invention is a hard disk device comprising a recording medium; a drive mechanism to rotation-drive the recording medium; a magnetic head to write data in the recording medium and read out the data from the recording medium; a drive mechanism to position-control the magnetic head; and a circuit substrate to control each of the drive mechanism, wherein the circuit substrate is configured so that it includes a component mounting unit on which a semiconductor device to be flip-chip-mounted is mounted, and so that an electrode of the component mounting unit is formed by an exposed section of a wiring pattern defined by a solder resist coating film, and the electrode includes an expanded section formed at the exposed section by protruding in a direction crossing a length direction of an exposed wiring pattern.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a plan view illustrating an electrode structure of a printed-wiring board according to an embodiment of the present invention;

FIG. 2 is an expanded plane view illustrating a part of the electrode structure illustrated in FIG. 1;

FIG. 3 is a sectional side view along with an X-X line illustrated in FIG. 2;

FIG. 4 is a sectional side view along with a Y-Y line illustrated in FIG. 2;

FIG. 5 is a plan view illustrating another electrode shape applicable to the embodiment of the present invention;

FIG. 6 is a plan view illustrating further electrode shape applicable to the embodiment of the present invention; and

FIG. 7 is an exploded perspective view illustrating a configuration of a hard disk device structured by applying the present invention.

### DETAILED DESCRIPTION

Various embodiments according to the invention will be described hereinafter with reference to the accompanying drawings.

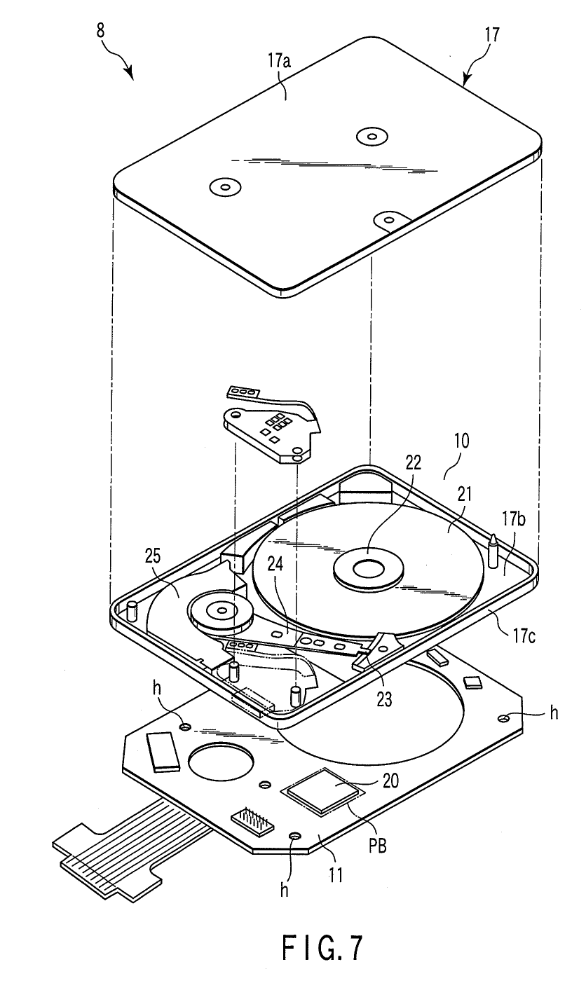

An embodiment of the present invention will be described hereinafter with reference to the accompanying drawings. FIG. 7 depicts a configuration of a hard disk device with a circuit board configured by using a printed-wiring board regarding the present invention mounted thereon.

A hard disk device 8 is configured to include a device main body 10, and a control circuit board 11.

The main body 10 includes a case 17 having an upper wall 17a, a lower wall 17b, and a side wall 17c, and a magnetic disk 21, a spindle motor 22, a magnetic head 23, a head actuator 24, a voice coil motor 25, etc., stored in the case 17.

The control circuit board 11 has engaging halls h which engage with protruded parts (not shown) protruded from the lower wall 17b of the main body 10, and is mounted on the exterior lower surface part of the case 17 in a state in which the engaging halls h are engaged with the protruded parts of the lower wall 17b.

The control circuit board 11 houses a functional circuit, which controls hardware stored in the case 17, writes data in the magnetic disk 21 with the magnetic head 23, and reads out the data from the magnetic disk 21. As for one constituent element of the functional circuit, a semiconductor device 20 of a bare chip structure is mounted in a flip-chip manner to be disposed on a prescribed component mounting section PB on the control circuit board 11.

The control circuit board 11 provided with the component mounting section PB is structured by using a printed-wiring board according to one embodiment of the present invention.

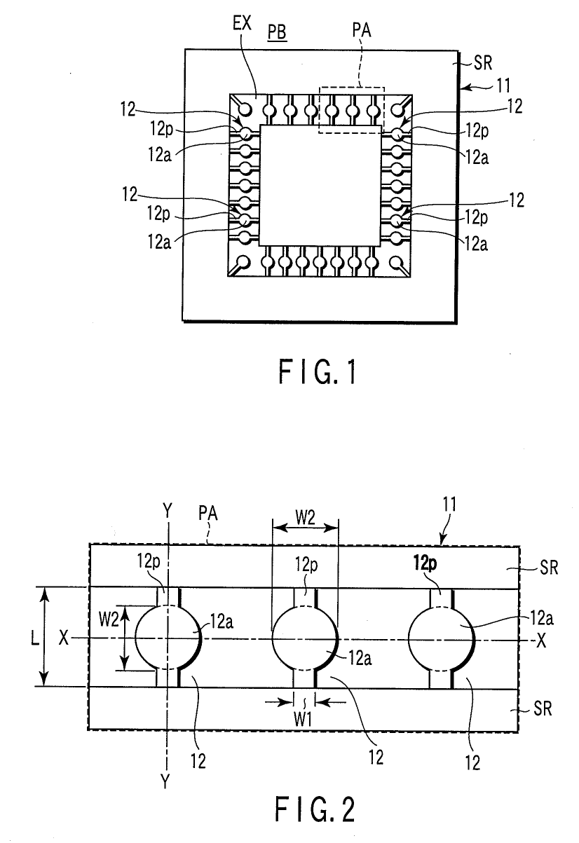

FIG. 1 to FIG. 4 each depicts a solder bonding structure configured in the component mounting section PB of a printed-wiring board according to one embodiment of the present invention.

FIG. 1 shows an enlargement view of a part of the component mounting section PB provided in the printed-wiring board 11 shown in FIG. 7 according to one embodiment of the present invention, with the IC chip 20 removed.

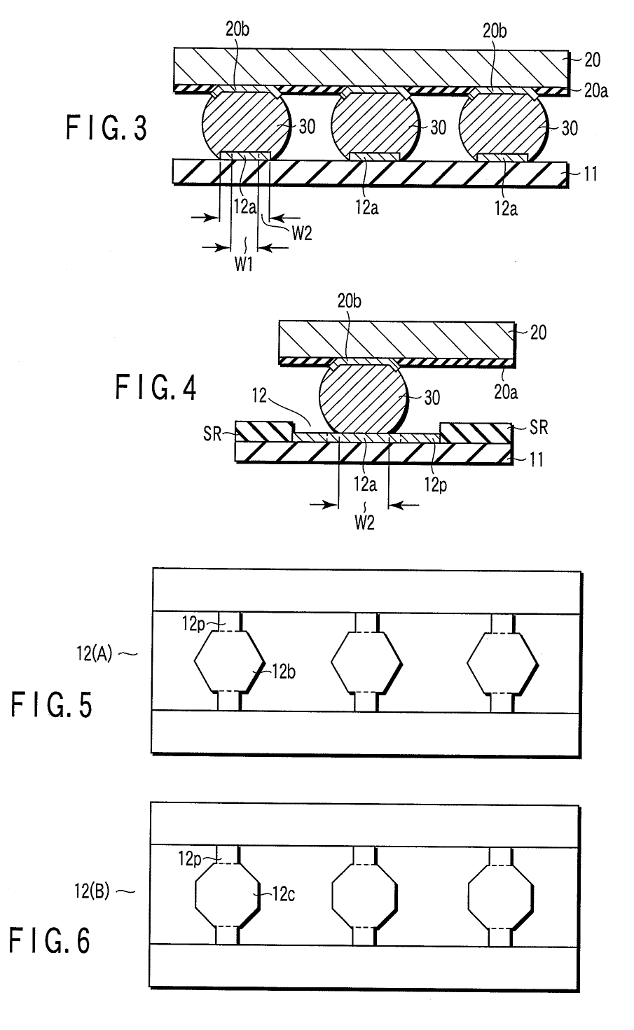

As shown in FIG. 1, the printed wiring board 11 is provided with an exposing section EX in which a plurality of electrodes 12 for bonding a semiconductor device (IC chip 20 in this case) to be flip-chip-mounted are disposed. The electrodes 12 are formed of sections of wiring patterns exposed in the exposing section EX defined by a solder resist coating film SR on the component mounting face or the component mounting section PB. A semiconductor device such as the IC chip 20 shown in FIG. 3, FIG. 4 and FIG. 7 of the bare chip structure is bonded by soldering on the electrodes 12.

FIG. 2 shows an expanded view of a part PA of the section PB in which three electrodes 12 are formed on the printed-wiring board 11.

The electrodes 12 each has, as shown in FIG. 2, an expanded section 12a expanding in a line width direction of wiring patterns 12p formed in the board 11, and each of the electrodes 12 is configured as a bonding electrode for the IC chip 20 at the expanded section 12a. The expanded sections 12a of the electrodes 12 have each expanded parts expanded in directions crossing the length directions of the wiring patterns 12p.

The shape of the electrode 12 is determined so that the electrode 12 has the shape and the area corresponding to a shape and an area of an under bump metal 20b mounted in an opening of the passivation 20a formed on the under surface of the IC chip 20 as shown in FIG. 3, FIG. 4. Namely, the shape and the area of the electrode 12 should be determined so that those of the electrode 12 match a bonding face of the under bump metal 20b which fills the opening of the passivation 20a. Thus, each electrode 12 shown in FIG. 1 and FIG. 2 has a shape in which the wiring pattern 12p and the circular expanded section 12a each forming the electrode 12 are combined with each other. Here, as shown in FIG. 2, the expanded section 12a has a projecting width W2 which is almost 2 times wider than the line width W1 of the wiring pattern 12p. More specifically, in the present embodiment, the circular expanded section 12a of the electrode 12 is formed to have a width W2 (diameter) of 80 μm when the length L of the exposed wiring pattern 12p is set to 140 μm, and the line width W1 thereof is set to 40 μm.

FIG. 3 and FIG. 4 show a state in which the IC chip 20 is mounted by soldering on the electrodes 12 via bumps, respectively. FIG. 3 shows a sectional side view along with the X-X line in FIG. 2, and FIG. 4 shows a sectional side view along with the Y-Y line in FIG. 2, respectively.

As shown in FIG. 3 and FIG. 4, the under bump metal 20b and the electrode 12 are solder-bonded by the bump 30 in a state in which the shape and the area of the solder-bonding face between the under bump metal 20b mounted at the opening of the passivation 20a and the top part of the bump 30 corresponds evenly to those between the under part of the bump 30 and the expanded section 12a of the electrode 12. In other words, the solder of the bump 30 is wetted and spread evenly both the two directions (X-X, Y-Y) between the under bump metal 20b and bump 30 and between the bump 30 and the electrode 12, while the under bump metal 20b fills the opening of the passivation 20a on the semiconductor device or the IC chip 20. According to the foregoing concrete example, since the line width W1 is thin as small as 40 μm, the solder of the bump 30 is wetted and spread around the whole circular section 12a of the diameter of 80 μm.

Therefore, as can be seen from FIGS. 3 and 4, the shapes of the solder bumps 30 are not extremely different between the cross-section X-X and the cross-section Y-Y, and the areas of wet-spreading of the solder bump 30 toward the IC passivation 20a side and the electrode 12 side of the printed-wiring board 11 become almost equal to each other. Since, the distortion occurring at the IC side passivation 20a and in the vicinity of the solder bump bonding section at the side of the electrode 12 due to the heat stress is reduced in comparison to a conventional printed-wiring board, the long-term bonding reliability with respect to a semiconductor component such as the IC chip 20 is extremely improved. Adopting the electrode shape of the electrode 12 regarding the aforementioned embodiment extremely improves the long-term bonding reliability of the solder bump at the flip-chip mounting section of the semiconductor component.

According to the embodiment given above, although the shape of the expanded section 12a of the electrode 12 is made circular so as to match the passivation opening, an expanded pattern structure of a polygon expanded section may be used. For example, a combination of the wiring pattern 12p and a hexagon expanded section 12b to form a pattern shape as shown in FIG. 5, or a combination of the wiring pattern 12p and an octagon expanded section 12c to form a pattern shape as shown in FIG. 6 may be used as the bonding electrode.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A printed-wiring board comprising a wiring pattern, the wiring pattern comprising an exposed part defined by a solder resist coating film to form an electrode for bonding a semiconductor device in a flip-chip-mounting manner, wherein the electrode comprises an expanded section spreading in a line width direction of the wiring pattern to form the electrode.

2. The printed-wiring board according to claim 1, wherein the expanded section comprises a protrusion of the wiring pattern in a direction crossing a length direction of the wiring pattern.

3. The printed-wiring board according to claim 1, wherein the electrode is configured to correspond to a shape of an opening of a passivation of a semiconductor device configured to be bonded by soldering to the electrode.

4. The printed-wiring board according to claim 1, wherein the electrode is configured to correspond to an area of an opening of a passivation of a semiconductor device configured to be bonded by soldering to the electrode.

5. The printed-wiring board according to claim 1, wherein the electrode is configured to correspond to a shape and an area of a bonding surface of an under bump metal disposed at a passivation opening of a semiconductor device configured to be bonded by soldering to the electrode.

6. The printed-wiring board according to claim 1, wherein the electrode comprises a shape formed by combining a part of a wiring pattern and a circular pattern.

7. The printed-wiring board according to claim 1, wherein the electrode comprises a shape formed by combining a part of a wiring pattern and a polygon pattern.

8. The printed-wiring board according to claim 1, wherein the electrode comprises either a circular or a polygon pattern shape spreading in radial directions from an approximate center of the expanded section defined by a line extending in a length direction and a line extending in a width direction of the wiring pattern.

9. The printed-wiring board according to claim 1 wherein an expansion amount of the expanded section is defined by a line length and a line width of the wiring pattern.

10. The printed-wiring board according to claim 2, wherein the protrusion of the expanded section comprises a width approximately two times a line width of the wiring pattern.

11. The printed-wiring board according to claim 9, wherein the protrusion of the expanded section comprises a width of 80 μm when a length and the line width of the wiring pattern are 140 μm and 40 μm, respectively.

12. A method for forming an electrode of a printed-wiring board for bonding a semiconductor device in a flip-chip-mounting manner is formed in an exposed section of a wiring pattern defined by a solder resist coating film, comprising:
forming the electrode for semiconductor device bonding by providing an expanded section in the wiring pattern spreading in a line width direction of the wiring pattern.

13. The method for forming the electrode of the printed-wiring board according to claim 12, further comprising:
forming the expanded section by protruding it in a direction crossing a length direction of the wiring pattern.

14. The method for forming the electrode of the printed-wiring board according to claim 13, wherein the electrode comprises a shape corresponding to a shape of an opening of a passivation of the semiconductor device to be bonded by soldering to the electrode.

15. The method for forming the electrode of the printed-wiring board according to claim 13, wherein the electrode comprises an area corresponding to an area of an opening of a passivation of the semiconductor device to be bonded by soldering to the electrode.

16. The method for forming the electrode of the printed-wiring board according to claim 13, wherein the electrode comprises a shape and area corresponding to those of a bonding section of an under bump metal disposed on an opening of a passivation of a semiconductor device to be bonded by soldering to the electrode.

17. The method for forming the electrode of the printed-wiring board according to claim 13, wherein the electrode comprises a combination shape of the wiring pattern and a circular pattern.

18. The method for forming the electrode of the printed-wiring board according to claim 13, wherein the electrode comprises a combination shape of the wiring pattern and a polygon pattern.

19. A hard disk device comprising:
a recording medium;
a first drive mechanism configured to drive the recording medium;
a second drive mechanism configured to drive a magnetic head to write data in the recording medium, configured to read out the data from the recording medium, and configured to position-control the magnetic head; and
a circuit board configured to control each of the first and second drive mechanisms;
wherein the circuit board comprises a component mounting section configured for mounting a semiconductor device in a flip-chip-mounting manner, wherein an electrode of the component mounting section is formed in an exposed section of a wiring pattern defined by a solder resist coating film, and wherein the electrode comprises an expanded section formed at the exposed section and protruding in a direction crossing a length direction of the exposed section of the wiring pattern.
